(19) United States
(12) Patent Application Publication
(10) Pub. No.: US 2016/0205774 A1
(43) Pub. Date: Jul. 14, 2016

(54) LIQUID GLASS APPLICATION

(71) Applicant: Yu-Chun CHANG, Taiwan (CN)

(72) Inventor: Yu-Chun Chang, Jhubei (TW)

(21) Appl. No.: 14/916,994

(22) PCT Filed: Sep. 6, 2013
(86) PCT No.: PCT/CN2013/083038

§ 371 Date: Mar. 4, 2016

(51) Int. Cl. H05K 1/03; H05K 3/28; H05K 3/00; H05K 3/06; C03B 23/02; C03B 19/12

(52) U.S. Cl. CPC H05K 1/0306; C03B 23/02; C03B 19/12; H05K 1/032; H05K 3/007; H05K 3/064; H05K 3/28

(57) ABSTRACT

A liquid glass application is provided, which uses liquid glass to prepare a substrate having conductive posts, a substrate embedded with a circuit and a glass membrane. The liquid glass possesses a large number of usage convenience features. Therefore, a preparation cost can be greatly reduced. Besides, a traditional glass configuration limit is broken and a glass thickness can be reduced remarkably, thereby meeting nowadays requirements of lightness, thinness, shortness and smallness on electronic products.

### BACKGROUND OF THE INVENTION

1. Field of the Invention

The present invention relates to glass applications, and, more particularly, to a liquid glass application.

2. Description of Related Art

Along with the progress of semiconductor processing technologies, more and more electronic products have been applied in semiconductor processes.

However, the conventional semiconductor processes can only use semiconductor materials as dielectric layers and insulating layers. The conventional semiconductor materials are generally required to be formed under a high-vacuum high-temperature environment by using expensive equipments and most of the semiconductor materials have a poor light transmittance. Therefore, the practical application of the semiconductor materials is seriously limited.

Although glass substrates are later developed to replace semiconductor substrates, forming via holes, recesses or through holes on a glass substrate is quite difficult, not environment friendly (for example, due to the use of highly toxic hydrofluoric acid) and there are many limits on shapes.

Therefore, how to overcome the above-described drawbacks and effectively use a glass material that eliminates the need of a high temperature process and expensive equipments and has a better light transmittance and a wider application area has become critical.

### SUMMARY OF THE INVENTION

In view of the above-described drawbacks, a primary object of the present invention is to provide a liquid glass application so as to greatly reduce a glass thickness and meet nowadays requirements of lightness, thinness, shortness and smallness on electronic products.

The present invention provides a method for fabricating a substrate, which comprises: forming a plurality of conductive posts on a carrier board; coating a liquid glass layer on the carrier board to encapsulate the conductive posts, wherein a top surface of the liquid glass layer is flush with top ends of the conductive posts; baking at a baking temperature between 50 and 100° C.; irradiating with UV light; and removing the carrier board.

The present invention provides a substrate, which comprises: a glass base having a thickness of 2 to 25 μm; and a plurality of conductive posts penetrating two surfaces of the glass base.

The present invention provides a substrate, which comprises: a polyimide base having a thickness of 2 to 100 μm; and a plurality of conductive posts penetrating two surfaces of the polyimide base.

The present invention provides a method for fabricating a substrate embedded with a circuit, which comprises: forming on a carrier board a redistribution layer (RDL) structure that is comprised of at least a circuit layer and at least a glass layer alternately stacked on each other, the glass layer being formed by sequentially performing the steps of coating a liquid glass layer, baking at a baking temperature between 50 and 100° C., and irradiating with UV light; and removing the carrier board.

The present invention provides a substrate embedded with a circuit, which comprises: an RDL structure comprised of at least a circuit layer and at least a glass layer alternately stacked on each other, wherein the glass layer has a thickness of 2 to 25 μm.

The present invention provides a method for fabricating a glass membrane, which comprises: coating a liquid glass layer on a carrier film; baking at a baking temperature between 50 and 100° C.; impressing a concave-convex pattern on a surface of the liquid glass layer and irradiating with UV light; and removing the carrier film.

The present invention provides a glass membrane, which comprises: a glass board having a regular or irregular concave-convex pattern on a surface thereof, wherein the glass board has a thickness of 2 to 25 μm.

Therefore, the photosensitive liquid glass application according to the present invention is operated with simple steps at a low temperature under a common atmosphere environment without the need of expensive equipments, and has a good light transmittance. Further, there is almost no limit on shape in formation of photosensitive liquid glass. As such, the cost is greatly reduced and the application area is expanded.

### BRIEF DESCRIPTION OF DRAWINGS

FIGS. 1A to 1J are cross-sectional views showing a substrate and a method for fabricating the same according to the present invention.

FIGS. 2A to 2C are cross-sectional views showing a substrate embedded with a circuit and a method for fabricating the same according to the present invention.

FIGS. 3A to 3D are cross-sectional views showing a substrate embedded with a circuit and a method for fabricating the same according to the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that the structures, scales, sizes etc. shown in the drawings of the specification are only used in combination with the contents disclosed in the specification so as to be understood and read by those in the art and are not intended to limit the present invention. Any modification to the structures, change in the scales or adjustment of the sizes should still fall within the scope covered by the technical means disclosed by the present invention provided that the functions and objects that can be achieved by the present invention are not affected. In addition, terms such as “on”, “top”, “flush”, “side”, “around”, “concave-convex”, “a” etc. used in the specification are merely for illustrative purposes and not used to limit the scope of implementation of the present invention. Any change or adjustment of the relative relationships is also considered as being within the scope of implementation of the present invention if there is no material change in the technical means.

### First Embodiment

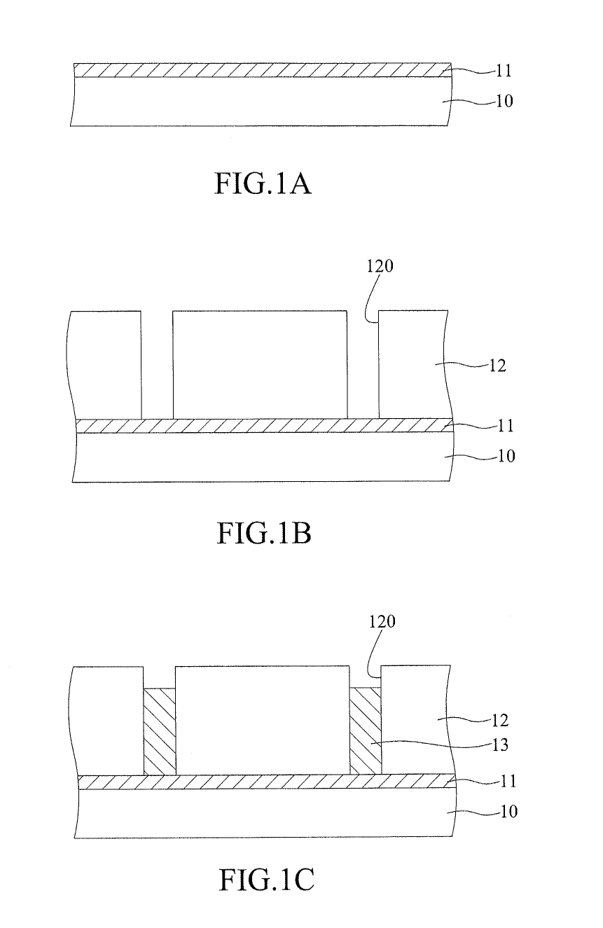

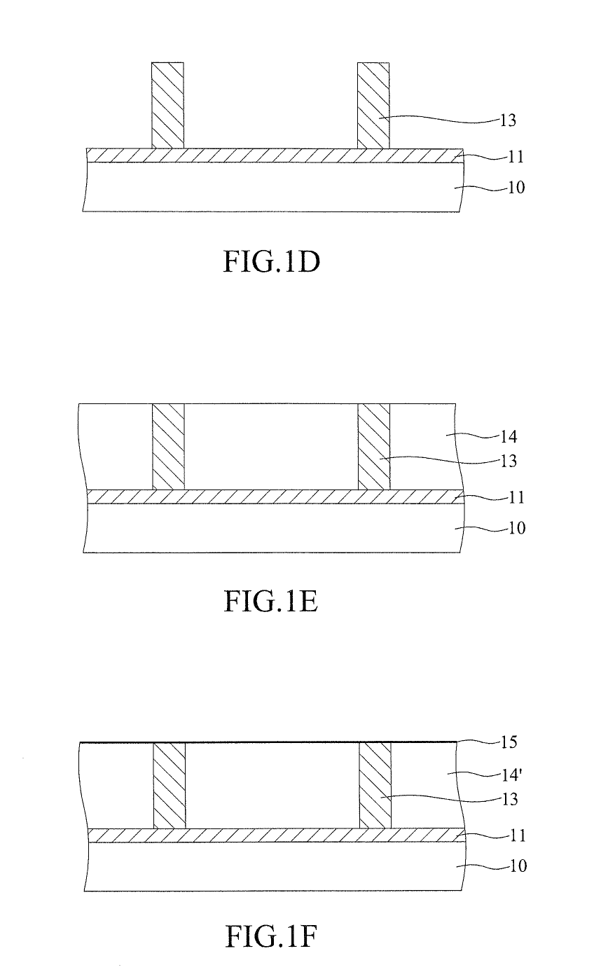

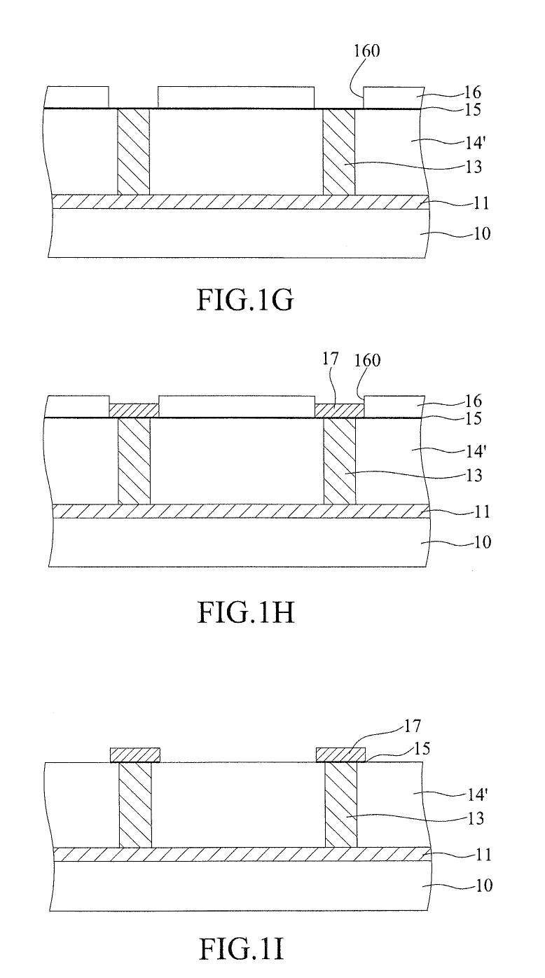

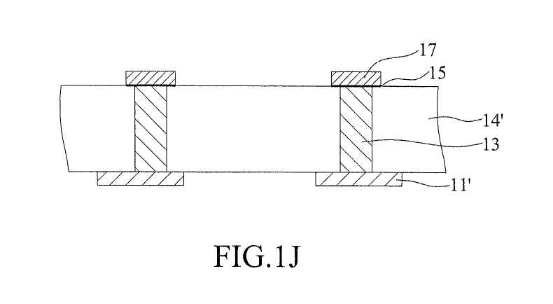

FIGS. 1A to 1J are cross-sectional views showing a substrate and a method for fabricating the same according to the present invention.

Referring to FIG. 1A, a metal foil 11 is formed on a carrier board 10.

Referring to FIG. 1B, a first resist layer 12 having a plurality of openings 120 is formed on the metal foil 11.

Referring to FIG. 1C, conductive posts 13 are respectively formed in the openings 120 by electroplating or deposition (for example, sputtering, evaporation, metal paste etc.), and an angle of 85 to 90° is formed between side walls of the conductive posts 13 and the carrier board 10 around the conductive posts 13. That is, the side walls of the conductive posts 13 have a good verticality.

Referring to FIG. 1D, the first resist layer 12 is removed.

Referring to FIG. 1E, a liquid glass layer 14 is coated on the metal foil 11 to encapsulate the conductive posts 13. The liquid glass layer 14 has a thickness of 2 to 25 μm, and a top surface of the liquid glass layer 14 is flush with top ends of the conductive posts 13. The liquid glass layer 14 is baked at a baking temperature between 50 and 100° C., preferably between 70 and 95° C., and at best at 85° C., and the baking takes 3 to 55 minutes. Then, the liquid glass layer 14 is irradiated with UV light so as to be cured into a glass base 14′.

Referring to FIG. 1F, a conductive layer 15 is formed on the top surface of the glass base 14′ and the top ends of the conductive posts 13.

Referring to FIG. 1G a second resist layer 16 having a plurality of openings 160 is formed on the conductive layer 15.

Referring to FIG. 1H, a first circuit layer 17 electrically connected to the conductive posts 13 is formed in the openings 160.

Referring to FIG. II, the second resist layer 16 and the conductive layer 15 covered by the second resist layer 16 are removed.

Referring to FIG. 1J, the carrier board 10 is removed, and the metal foil 11 is patterned into a second circuit layer 11′ electrically connected to the conductive posts 13.

In an embodiment, the metal foil 11, the first resist layer 12, the conductive layer 15 and the second resist layer 16 can be provided according to need, and are not essential components.

The present invention further provides a substrate, which has: a glass base 14′ having a thickness of 2 to 25 μm; and a plurality of conductive posts 13 penetrating two surfaces of the glass base 14′.

In an embodiment, an angle of 85 to 95° is formed between side walls of the conductive posts 13 and the surfaces of the glass base 14′.

In an embodiment, the substrate according to the present embodiment is an interposer and the glass base 14′ according to the present embodiment can be replaced with a polyimide base that has a thickness of 2 to 100 μm, preferably 2 to 25 μm. The other features of the polyimide base are identical to the glass base 14′, and detailed description thereof is omitted herein.

### Second Embodiment

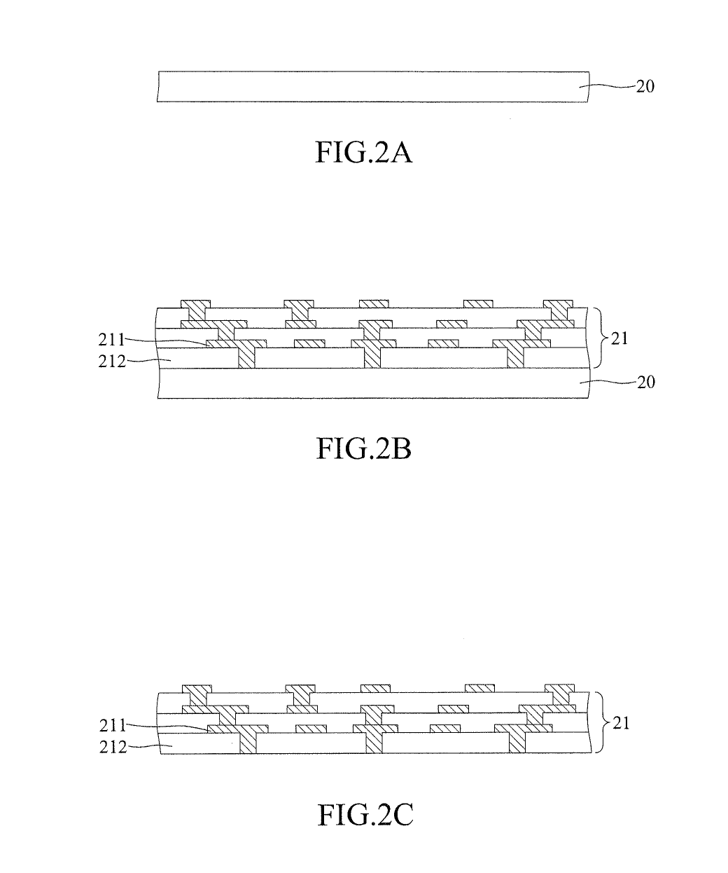

FIGS. 2A to 2C are cross-sectional views showing a substrate embedded with a circuit and a method for fabricating the same according to the present invention.

Referring to FIG. 2A, a carrier board 20 is provided.

Referring to FIG. 2B, an RDL structure 21 is formed on the carrier board 20, and includes at least a circuit layer 211 and at least a glass layer 212 alternately stacked on each other. In an embodiment, the glass layer 212 is formed by sequentially performing the steps of coating a liquid glass layer, baking at a baking temperature between 50 and 100° C., and irradiating with UV light. The baking temperature is preferably between 70 and 95° C. and at best at 85° C., and the baking takes 3 to 55 minutes depending on a thickness of the glass layer 212. The thickness of the glass layer 212 is in a range of 2 to 25 μm.

Referring to FIG. 2C, the carrier board 20 is removed.

The present invention further provides a substrate embedded with a circuit, which has: an RDL structure 21 consisting of at least a circuit layer 211 and at least a glass layer 212 alternately stacked on each other, wherein the glass layer 212 has a thickness of 2 to 25 μm.

It an embodiment, the substrate according to the present embodiment can be a core board, and can be directly replaced with a conventional silicon interposer so as to redistribute a circuit directly in the core board.

### Third Embodiment

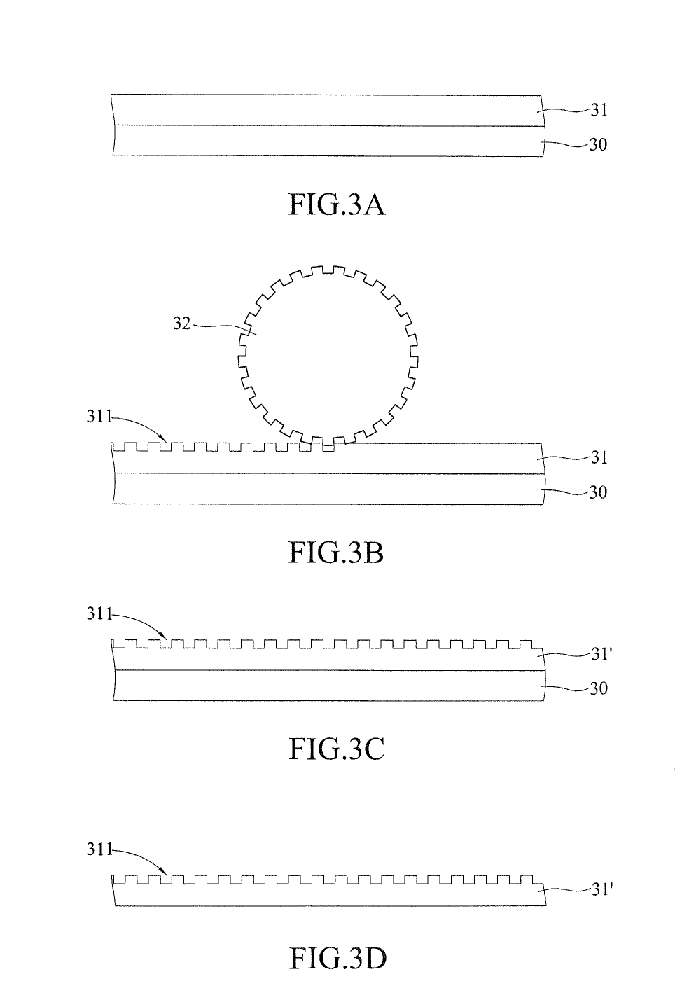

FIGS. 3A to 3D are cross-sectional views showing a glass membrane and a method for fabricating the same according to the present invention.

Referring to FIG. 3A, a liquid glass layer 31 is coated on a carrier film 30 and baked at a baking temperature between 50 and 100° C. The baking temperature is preferably between 70 and 95° C. and at best at 85° C., and the baking takes 3 to 55 minute depending on a thickness of the liquid glass layer 31. The thickness of the liquid glass layer 31 is in a range of 2 to 25 μm.

Referring to FIGS. 3B and 3C, a roller 32 is used to impress an irregular or regular concave-convex pattern 311 on a surface of the liquid glass layer 31, and the liquid glass layer 31 is irradiated with UV light through the carrier film 30 so as to be cured into a glass board 31′.

Referring to FIG. 3D, the carrier film 30 is removed.

The present invention further provides a glass membrane, which has: a glass board 31′ having an irregular or regular concave-convex pattern 311 on a surface thereof, wherein the glass board 31′ has a thickness of 2 to 25 μm.

It an embodiment, a release layer can be formed on the carrier film before coating of the liquid glass layer so as to facilitate the final removal of the carrier film, and the glass membrane according to the present embodiment can be applied in screen protection, screen anti-glare, and light condensing or dispersing for light sources of displays.

Therefore, compared with the prior art, since the photosensitive liquid glass application according to the present invention is operated with simple steps at a low temperature under a common atmosphere environment without the need of expensive equipments, and has a good light transmittance, the cost is effectively saved. In addition, the photosensitive liquid glass can be formed conveniently and there is almost no limit on shape. As such, through holes with a good verticality and a very thin thickness can be achieved and the application area is expanded.

The description of the above embodiments is only to illustrate the principle and effect of the present invention, but is not intended to limit the present invention. Any person skilled in the art can make modification or variation to the above embodiments without departing from the sprit and scope of the present invention. Therefore, the scope of the present invention is set forth in the appended claims.

1. A method for fabricating a substrate, comprising:
forming a plurality of conductive posts on a carrier board;
coating a liquid glass layer on the carrier board to encapsulate the conductive posts, wherein a top surface of the liquid glass layer is flush with top ends of the conductive posts;
baking at a baking temperature between 50 and 100° C.;
irradiating with UV light; and
removing the carrier board.

2. The method of claim 1, wherein the baking temperature is preferably between 70 and 95° C.

3. The method of claim 1, wherein the baking takes 3 to 55 minutes.

4. The method of claim 1, wherein the liquid glass layer has a thickness of 2 to 25 μm.

5. The method of claim 1, wherein the conductive posts are formed by electroplating or deposition.

6. The method of claim 1, wherein forming the conductive posts comprises the steps of:
forming on the carrier board a resist layer having a plurality of openings;
forming the conductive posts in the openings of the resist layer; and
removing the resist layer.

7. The method of claim 1, wherein an angle of 85 to 90° is formed between side walls of the conductive posts and the carrier board around the conductive posts.

8. A substrate, comprising:
a glass base having a thickness of 2 to 25 μm; and
a plurality of conductive posts penetrating two surfaces of the glass base.

9. The substrate of claim 8, wherein an angle of 85 to 95° is formed between side walls of the conductive posts and the surfaces of the glass base.

10. A substrate, comprising:
a polyimide base having a thickness of 2 to 100 μm; and
a plurality of conductive posts penetrating two surfaces of the polyimide base.

11. The substrate of claim 10, wherein an angle of 85 to 95° is formed between side walls of the conductive posts and the surfaces of the polyimide base.

12. The substrate of claim 10, wherein the thickness of the polyimide base is in a range of 2 to 25 μm.

13. A method for fabricating a substrate embedded with a circuit, comprising:
forming on a carrier board a redistribution layer structure comprised of at least a circuit layer and at least a glass layer alternately stacked on each other, the glass layer being formed by sequentially performing the steps of coating a liquid glass layer, baking at a baking temperature between 50 and 100° C., and irradiating with UV light; and
removing the carrier board.

14. The method of claim 13, wherein the baking temperature is preferably between 70 and 95° C.

15. The method of claim 13, wherein the baking takes 3 to 55 minutes depending on the thickness of the glass layer.

16. The method of claim 13, wherein the glass layer has a thickness of 2 to 25 μm.

17. A substrate embedded with a circuit, comprising:
a redistribution layer structure comprised of at least a circuit layer and at least a glass layer alternately stacked on each other, wherein the glass layer has a thickness of 2 to 25 μm.

18. A method for fabricating a glass membrane, comprising:
coating a liquid glass layer on a carrier film;
baking at a baking temperature between 50 and 100° C.;
impressing a concave-convex pattern on a surface of the liquid glass layer and irradiating with UV light; and
removing the carrier film.

19. The method of claim 18, wherein the baking temperature is preferably between 70 and 95° C.

20. The method of claim 18, wherein the baking takes 3 to 55 minutes depending on the thickness of the liquid glass layer.

21. The method of claim 18, wherein the liquid glass layer has a thickness of 2 to 25 μm.

22. The method of claim 18, wherein the impressing is performed by using a roller.

23. A glass membrane, comprising:
a glass board having a regular or irregular concave-convex pattern on a surface thereof, wherein the glass board has a thickness of 2 to 25 μm.
